(19) United States
(12) Patent Application Publication
(10) Pub. No.: US 2011/0220190 A1
(43) Pub. Date: Sep. 15, 2011

(54) SOLAR CELL HAVING A GRADED BUFFER LAYER

(76) Inventors: Rong-Ren LEE, Hsinchu City (TW); Shiuan-Leh Lin, Hsinchu City (TW); Shin-Chang Lee, Hsinchu City (TW)

(21) Appl. No.: 13/051,266

(22) Filed: Mar. 18, 2011

(30) Foreign Application Priority Data
Mar. 12, 2010 (TW) 099107438
Mar. 19, 2010 (CN) 201010142921.3

(51) Int. Cl. H01L 31/06

(52) U.S. Cl. 136/255

(57) ABSTRACT

An IMM solar cell includes a substrate, a bottom cell on the substrate; a graded buffer layer on the bottom cell; a middle cell on the graded buffer layer; a top cell on the middle cell.

### RELATED APPLICATION DATA

This application claims the right of priority based on CN application Ser. No. 201010142921.3 filed on Mar. 19, 2010, the contents of which are incorporated herein by reference in their entirety.

### BACKGROUND

1. Technical Field

The application relates to a solar cell having a graded buffer layer and the manufacturing method thereof.

2. Description of the Related Art

Light-emitting diodes (LED), solar cells, or photo-diodes are all optoelectronic devices. Recently, researchers have been actively developing the technologies related to alternative energy and renewable energy due to the shortage of fossil fuel and the great emphasis on the environment conservation. The solar cell is one of the most important options because the solar cell can directly transmit solar energy into electrical energy without producing the hazardous material, such as carbon dioxide or nitride material, that poisons the environment.

The inverted metamorphic multijunction (IMM) solar cell is one preferred structure and is formed by sequentially growing GaInP cell and GaAs cell which are lattice-matched (LM), and then growing InGaAs cell which is lattice-mismatch (LM) with the GaAs cell, and removing the growth substrate after bonding to the InGaAs cell, therefore an IMM solar cell is formed. Despite IMM structure improves the energy conversion efficiency, the epitaxy quality for the InGaAs cell with lower bandgap energy is not good enough. The lattice-dislocations are still incurred in the InGaAs cell.

The soler cell described above or others optoelectronic device comprise substrate and electrode, and can be further mounted to a submount by solder or glue materials to form a light-emitting apparatus or a photovoltaic apparatus. Nevertheless, the submount further comprises a circuit connecting to the electrode of the optoelectronic device by a conductive structure, such as metal wire.

### SUMMARY

The present disclosure provides an IMM solar cell comprising a supporter; a bottom cell on the supporter; a graded buffer layer on the bottom cell; a middle cell on the graded buffer layer; and a top cell on the middle cell.

### BRIEF DESCRIPTION OF THE DRAWINGS

FIG. 1 illustrates an IMM solar cell structure in accordance with a first embodiment of the present disclosure.

FIG. 2 illustrates a graded buffer layer of the first embodiment in accordance with the present disclosure.

### DETAILED DESCRIPTION OF PREFERRED EMBODIMENTS

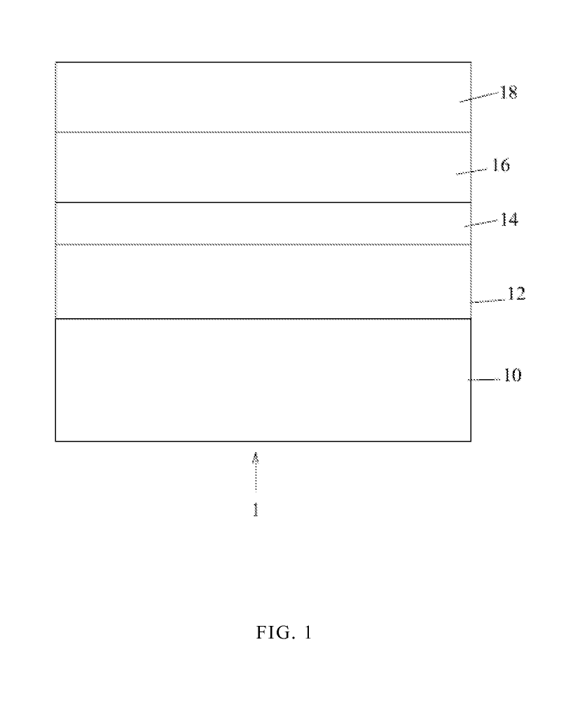

In FIG. 1, an IMM solar cell 1 comprises a supporter 10; a bottom cell 12 comprising a bottom p-n junction on the supporter 10; a graded buffer layer 14 on the bottom cell 12; a middle cell 16 comprising a middle p-n junction on the graded buffer layer 14; and a top cell 18 comprising a top p-n junction on the middle cell 16. A bandgap energy of the top cell 18 (or the top p-n junction) is greater than those of the middle cell 16 (or the middle p-n junction) and the bottom cell 12 (or the bottom p-n junction). The material of the top cell 18 comprises InGaP, InGaAs, AlGaAs, or AlGaInP. A bandgap energy of the middle cell 16 or the middle p-n junction is greater than the bottom cell 12 or the bottom p-n junction. The material of the middle cell comprises GaAs, GaInP, InGaAs, GaAsSb, or InGaAsN. The material of the bottom cell 12 comprises Ge, GaAs, or InGaAs. The top cell 18, middle cell 16, and the bottom cell 12 can convert light within different spectrum ranges to electrical current.

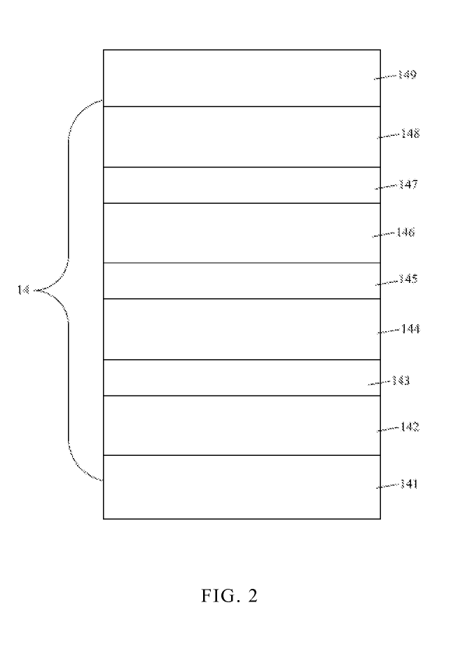

FIG. 2 discloses a detailed structure of the graded buffer layer 14. Please refer to FIG. 1 and FIG. 2, the graded buffer layer 14 comprises a first buffer layer 141 between the bottom cell 12 and the middle cell16; a plurality of sub-graded layers 142, 144, 146, and 148 formed between the first buffer layer 141 and the middle cell16; a plurality of co-doped intermediate layers 143, 145, 147 interposed correspondingly between the sub-graded layers 142 and 144, between the sub-graded layers 144 and 146, and between the sub-graded layers 146 and 148; and a second buffer layer 149 formed between the sub-graded layer 148 and the middle cell16. The first buffer layer 141 comprises the same lattice constant as the bottom cell 12 and provides a function to block thread dislocations from extending into the bottom cell 12. Therefore, the first buffer layer 141 comprises higher thread dislocation density than that of the bottom cell 12. Similarly, the second buffer layer 149 comprises the same lattice constant as the middle cell 16. The number of the sub-graded layers in the present embodiment is four (142, 144, 146, 148). However, it is still under the scope the present disclosure to form more or less than four sub-graded layers. The number of the co-doped intermediate layers in the present embodiment is three (143, 145, 147). However, it is still under the scope the present disclosure to form more or less than three co-doped intermediate layers. The first buffer layer 141 comprises at least one material selected from the group consisting of InGaAs, GaAs, AlGaAs, InGaP, and AlGaInP. The second buffer layer comprises GaAs or InGaP. The plurality of sub-graded layers comprises graded compositions so as to buffer the lattice constant difference between the bottom cell 12 and the middle cell 16. The sub-graded layer closest to the bottom cell 12 has a similar or the same lattice constant as the lattice constant of the bottom cell 12; The sub-graded layer closest to the middle cell 16 has similar or the same lattice constant as the lattice constant of the middle cell 16; and the lattice constants of the intervening sub-graded layers are gradually varied intermediately. The plurality of sub-graded layers comprises InₓGa₍₁₋ₓ₎P, InₓGa₍₁₋ₓ₎As, or (Al_{y}Ga_{(1-y)})ₓIn₍₁₋ₓ₎As, 0≦x≦1, 0≦y≦1, wherein the indium contents thereof are gradually varied in a direction away from the supporter 10 or in a direction away from the bottom cell 12. Specifically, the indium contents in the sub-graded layers are gradually varied decreasingly in a direction away from the supporter 10 or in a direction away from the bottom cell 12. The sub-graded layers 142, 144, 146, and/or 148 are doped with single n-type impurity, such as Si, Se, or S, and the doped concentration thereof are from about 10¹⁷ cm⁻³ to 10²⁰ cm⁻³. The co-doped intermediate layers 143, 145, and/or 147 are co-doped with two different impurities comprising tellurium and other n-type impurity, e.g. Si, Se, or S. The doped tellurium concentration of the co-doped intermediate layers is from about 10¹⁷ cm⁻³ to 10²⁰ cm⁻³, and is preferred greater than 10¹⁹ cm⁻³. The doped concentration of tellurium is preferred at least one order higher than that of the other n-type impurity, e.g. Si, Se, or S in the co-doped intermediate layers or the sub-graded layers. The material composition of the co-doped intermediate layer is similar to or the same as the adjacent sub-graded layer which is just formed before the co-doped intermediate layer. The thickness of the sub-graded layer is about 500˜5000 Å, and preferably 1000˜3000 Å. The thickness of the co-doped intermediate layer is about 1˜500 Å, and preferably 50˜300 Å, while it is noted that a greater or smaller thickness of the co-doped intermediate layer inversely affects the epitaxy quality. In addition, the thickness of the co-doped intermediate layer is normally smaller than the thickness of the sub-graded layer. The material for the co-doped intermediate layer comprises InGaP, InGaAs, or AlInGaAs.

Take the co-doped intermediate layer 143 as an example, the method for forming the co-doped intermediate layer 143 comprises firstly forming the sub-graded layer 144 in a growth chamber by a known MOCVD process, e.g. a process temperature around 480 to 580, and maintaining the process condition, e.g. gas flows, in the chamber after the sub-graded layer 144 are formed. Flowing Si₂H₆ gas as an Si impurity source along with diethyl-tellurium (DETe) as Te impurity source to form the co-doped intermediate layer 143. Therefore, the co-doped intermediate layer 143 comprises the same material composition with the sub-graded layer 144. The flow rate of DETe is controlled at around 50˜100 sccm (the flow rate scale should be varied in different deposition systems) to achieve a Te impurity concentration higher than Si impurity concentration. It is preferred to adjust the process parameter to form the co-doped intermediate layer 143 having Te impurity concentration at least one order greater than Si impurity concentration. The process method for forming the co-doped intermediate layer 145, 147 is similar to the method for forming the co-doped intermediate layer 143.

The method for forming the IMM solar cell 1 comprises sequentially growing the top cell 18 and the middle cell 16 on a growth substrate (not shown), which are both lattice-matched with the growth substrate, and then growing the bottom cell, which is lattice-mismatched with the top cell 18 and middle cell 16, on the middle cell 16. Then the bottom cell 12 is bonded to a supporter 10 by a conductive adhesive layer, e.g. metal or silver paste, and the growth substrate is removed after the bonding process to form the IMM solar cell 1. The graded buffer layer 14 is formed between the bottom cell 12 and the middle cell 16 for reducing the stress and the crystal dislocations generated by the lattice-mismatch between the bottom cell 12 and the middle cell 16, and improve the epitaxy quality of the bottom cell 12.

It will be apparent to those with ordinary skill in the art that various modifications and variations can be made to the methods in accordance with the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A solar cell comprising:
a supporter;
a bottom cell on the supporter;
a graded buffer layer on the bottom cell comprising a plurality of sub-graded layers not doped with tellurium, and a plurality of intermediate layers doped with tellurium interposed between two adjacent sub-graded layers; wherein a composition in the plurality of sub-graded layers is gradually varied in a direction away from the supporter; and
a middle cell on the graded buffer layer, lattice-mismatched with the bottom cell.

2. The solar cell of claim 1, further comprising a first buffer layer between the bottom cell and the graded buffer layer wherein the first buffer layer is lattice-matched with the bottom cell.

3. The solar cell of claim 1, further comprising a second buffer layer between the middle cell and the graded buffer layer wherein the second buffer layer is lattice-matched with the middle cell.

4. The solar cell of claim 1, wherein the plurality of sub-graded layers is doped with single n-type impurity other than tellurium.

5. The solar cell of claim 4, wherein the doped tellurium concentration in one of the intermediate layers is greater than the n-type impurity concentration.

6. The solar cell of claim 5, wherein the doped tellurium concentration in one of the intermediate layers is at least one order greater than the n-type impurity concentration.

7. The solar cell of claim 1, wherein each of the plurality of intermediate layers is co-doped with tellurium and the n-type impurity.

8. The solar cell of claim 7, wherein the doped tellurium concentration in one of the intermediate layers is at least one order greater than the n-type impurity concentration.

9. The solar cell of claim 1, wherein the thickness of one of the sub-graded layers is greater than the thickness of one of the intermediate layers.

10. The solar cell of claim 1, wherein the material composition of one of the intermediate layers is the same as the material composition of one of the adjacent sub-graded layers.

11. A solar cell comprising:
a first cell comprising a first p-n junction;
a second cell comprising a second p-n junction different from the first p-n junction;
a graded buffer layer interposed between the first cell and the second cell comprising a plurality of sub-graded layers having graded compositions gradually varied in a direction away from the first cell, and a plurality intermediate layers intervening any two adjacent sub-graded layers;
wherein one of the sub-graded layers is doped with only one n-type impurity, and one of the intermediate layers is co-doped with tellurium and the n-type impurity.

12. The solar cell of claim 11, further comprising a first buffer layer on the first cell wherein the first buffer layer is lattice-matched with the first cell.

13. The solar cell of claim 11, further comprising a second buffer layer on the second cell wherein the second buffer layer is lattice-matched with the second cell.

14. The solar cell of claim 11, wherein the n-type impurity comprises Si, Se, or S.

15. The solar cell of claim 11, wherein the doped tellurium concentration in one of the intermediate layers is greater than the n-type impurity concentration.

16. The solar cell of claim 15, wherein the doped tellurium concentration in one of the intermediate layers is at least one order greater than the n-type impurity concentration.

17. The solar cell of claim 11, wherein the doped tellurium concentration in one of the intermediate layers is at least one order greater than the n-type impurity concentration.

18. The solar cell of claim 11, wherein the thickness of one of the sub-graded layers is greater than the thickness of one of the intermediate layers.

19. The solar cell of claim 1, wherein the material composition of one of the intermediate layers is the same as the material composition of one of the adjacent sub-graded layers.
